(19) United States
(12) Patent Application Publication
(10) Pub. No.: US 2009/0034224 A1
(43) Pub. Date: Feb. 5, 2009

(54) Support arrangement

(76) Inventors: Armin Wiedemeier, Duebendorf (CH); Markus Weber, Watt-Regensdorf (CH); Markus Zbinden, Engelburg (CH); Walter Tschopp, Buetschwil (CH); Andreas Amacker, Winterthur (CH)

Correspondence Address: HARNESS, DICKEY & PIERCE, P.L.C., P.O. BOX 828, BLOOMFIELD HILLS, MI, 48303, US

(21) Appl. No.: 11/887,065

(22) PCT Filed: Feb. 14, 2006
(86) PCT No.: PCT/EP2006/001337

§ 371 Date: Nov. 26, 2007

(30) Foreign Application Priority Data
Apr. 1, 2005 (EP) 05007167.9

(51) Int. Cl. H05K 7/12; H05K 5/00; F16F 7/00

(52) U.S. Cl. 361/808; 267/141; 267/140.3; 211/26

(57) ABSTRACT

The invention relates to a support arrangement for an inner module in an outer module, particularly for an inner vibrating frame in an outer frame of an outer housing, with a damping device between the inner and outer modules for absorbing forces acting in up to three coordinate directions relative to the inner and outer modules. The damping device is essentially constructed as an elastic polymer profile, particularly two polymer profiles, running round between the inner and outer modules and that the inner and outer modules are constructed with a bearing device for the elastic polymer profile or profiles.

The invention relates to a support arrangement according to the preamble of claim 1 and to an equipment or instrument case or box having the support arrangement according to the invention.

Such support arrangements are used for protecting shock-sensitive modules against vibrations and oscillations in casings and housings. Such housings e.g. have an outer frame and an inner frame. Electrical and electronic modules are secured in conventional manner in the inner frame. Examples of such modules are measuring equipment for field tests or communications devices. The inner frame is in contact with the outer frame solely through so-called damping elements. As a result of said damping elements it is possible to not transfer to the inner frame vibrations and force actions on the outer frame, because the forces are at least largely absorbed by the damping elements. The conventionally used damping elements often have as the central element a spring, usually a spiral spring, in order to bring about the necessary damping action and are designed in the manner of car shock absorbers.

Generally the outer frame is constructed as a housing. To permit transportation of such a device in an easier manner, the outer frame has a closable cover. The aim is to give a good protection to modules installed in the inner frame against external environmental influences such as moisture or dirt. For this purpose a prior art housing has a sealing edge in the vicinity of the cover, so as in this way to ensure a tight closure of the housing. The cover is usually fixed to the housing by rotary locks.

For operating the modules installed in the inner housing it is necessary to remove the cover. The modules form on the side facing the cover opening and as a result of their front panels a planar front. As a result of the modules being fitted in the vibrating frame, which as a result of the damping elements is at a certain distance from the outer frame, in this case the housing, moisture and dirt can reach the back surfaces of the modules through said gap. Therefore in conventional housings a rubber bellows is provided and is fitted between the vibrating frame and the outer housing. For fixing purposes parts of said rubber bellows are secured under the front panels of the components.

The fitting of such a rubber bellows is firstly extremely complicated, because there is not much space for installation in the intermediate area. Secondly the vibration characteristics of the inner frame are negatively influenced by said rubber bellows, because they constitute an additional connection between inner housing and outer housing. As the rubber bellows is intended to serve as a seal, it must engage on both the inner and outer housings. This leads to a further connection between the two housings, apart from the existing connections through the damping elements.

A portable protective housing with vibration dampers is known from EP 0 327 809 A1. An attempt is made to shield the inner area of the inner frame inter alia by a metal mesh, a fabric or a foil with respect to the environment. This is in particular implemented on an EMC seal. Such a device also has a sealing action against dirt and the like.

In this construction the problem also arises that the additional seals unfavourably influence the vibration characteristics of the inner frame.

For sealing and damping forces in said protective housing use is made of two complicated, separate systems with damping elements and rubber bellows means.

The object of the invention is to provide a simplified design principle for a support arrangement and an instrument case, which is suitable for implementing both functions, namely damping and sealing, and is flexible and adaptable for this field of application.

According to the invention the object is achieved by a support arrangement having the features of claim 1. According thereto the damping device is essentially constructed as at least one elastic polymer profile passing round between the inner and outer modules and having a sealing action between said inner and outer modules, particularly with two polymer profiles and that also the inner and outer modules are constructed with a bearing device for the elastic polymer profile or profiles.

The invention is also implemented in an instrument case according to claim 18 with an outer housing and an inner vibrating frame fitted therein.

Further advantageous embodiments are given in the dependent claims.

It is a fundamental idea of the invention to combine the damping function and sealing function in one system or arrangement. This is achieved in that the damping device is formed from an elastic polymer profile.

Moreover the inner and outer modules have at least one bearing device for the elastic polymer profile. As a result of said bearing device it is possible to appropriately fix the polymer profile between the outer frame and the inner frame so as in this way to provide a particularly good damping. Moreover, with said damping arrangement it is ensured that the conventional damping elements usually comprising springs are rendered superfluous.

Through the use of a polymer profile between the inner and outer modules the gap between said two modules is closed. Consequently the sealing of the electrical and electronic modules installed in the inner module is improved and ensured.

In principle, the bearing device can be in any shape or form which is suitable to fix or clamp the elastic polymer profile in a position between the inner and outer modules and without negatively influencing the damping characteristics of the polymer profile. It has proved particularly advantageous, for the bearing device to have two inclined surfaces which are directed against one another and which are in particular parallel and between which the polymer profile is located. Through the construction of the bearing device with two inclined surfaces a particularly good damping through the polymer profile can be obtained. The polymer profile is also adequately fixed in position and place by said inclined surfaces, so that as a damping element it cannot slide.

For an optimization of the inner module damping, in each case at least one bearing device is provided on both end regions of the inner module for the polymer profile and the two bearing devices are substantially mirror symmetrical to the central axis of the inner module. Through such a design of the bearing devices on both end regions of the inner module, vibrations can be particularly adequately absorbed and damped. As a result of the axially symmetrical design of the bearing device impacts or shocks from the front or rear can be adequately damped by the in each case nearest polymer profile without giving rise to significant vibration amplitudes. Furthermore, as a result of the mirror symmetry of the bearing device there is

a good centering of the inner module in the outer module with respect to the central axis.

It is particularly advantageous for the bearing device to be constructed as a guiding or clamping device. As a result the clamped polymer profile is held in the desired position without additional fixing means. The clamping device can also exert a desired pretension on the polymer profile, so that the damping characteristic of the polymer profile can be adjusted in accordance with the characteristics of the inner module, as a function of the weight. The guiding device ensures that even in the case of significant vibration deflections the polymer profile is guided back again into the desired starting position. The guiding device preferably has a cage-like construction and this prevents a deflection of the profile during vibrations. It is also possible to provide extensions on the edges of the bearing device. As a result the polymer profile is well fixed and in spite of this can react very flexibly to external vibration excitation, i.e. its full damping action can be evolved.

To more appropriately adapt the damping characteristics of the polymer profile, it can be constructed as a solid or hollow profile. Compared with a hollow profile a solid profile has the advantage that it is possible to better absorb and take up greater weights and forces, which can e.g. compress significantly a hollow profile. A hollow profile has the advantage that it can deform more flexibly and consequently a greater damping action can be achieved when smaller forces are involved.

To be able to bring about a good damping action between the outer module and the inner module through the polymer profile, it is in large-area operative connection with the bearing device. As a result of a large-area operative connection the forces acting on the polymer profile from the outer module are absorbed by the entire profile. Thus, there is no punctiform loading of the profile, which would reduce the service life of the polymers. A large-area operative connection also has the advantage that the forces acting on the polymer profile are absorbed by the entire profile and consequently, considered in punctiform manner, the profile does not have to have such a high degree of damping.

Fundamentally the polymer profile can have a random shape. It is particularly appropriate for it to be constructed as an annular, oval or circular hollow profile. An advantage of an annular, oval or circular polymer profile shape is that on placing the profile between the two modules it is not necessary to ensure that a specific position with respect to the two engaging modules is taken. Thus, there is no area of the profile which must be directed towards the outer frame and also no area which must be directed towards the inner frame. Moreover as a result of the annular shape a particularly good, troublefree force transfer from the outer module to the polymer profile can be brought about and due to the cavity present a particularly good damping action is achieved. Through the confluence of these two characteristics of annular, hollow profile, an easily handlable, but still good damping polymer profile is formed.

In an advantageous embodiment the polymer profile is constructed in integral, allround or segmented form. An integral construction of the polymer profile is particularly cost effective and easy to produce. However, through a segmentation of the polymer profile it can be achieved that in partial areas it can be constructed with different hardness and/or damping characteristics. This procedure offers the possibility of matching the polymer profile specifically to certain vibration behaviours which arise. Thus, e.g. during transportation with a lorry jolting movements occur, which are cushioned differently to impacts or shocks and which are initiated by dropping on the ground or floor. There can also be an appropriate interplay between different hardness and damping characteristics, which can be advantageously used in the case of a segmentation for bringing about a good damping of different vibration types through individual segments being in each case specifically matched to one vibration type. Such a matching effect can be brought about by using different polymers.

Another possibility for varying the hardness and damping characteristics involves not placing the different polymers in individual segments, but instead using an integrated transition between the individual polymers. This makes it possible to vary the characteristics of the profile continuously or also abruptly for certain areas.

It is also possible to vary and adjust the damping and/or hardness characteristics of the polymer profile by means of a medium introduced into the hollow profile or individual segments thereof. The clamping of the polymer profile in the bearing device can also be influenced by this. The hollow profile can e.g. be filled with suitable fluids. Another possibility is to fill the hollow profile with higher pressure air. It is also conceivable to foam-fill the cavity with a suitable foam. If the hollow profile is segmented, it is possible to introduce different media into the individual segments of said profile in order to achieve different damping and hardness characteristics. This can be utilized for matching the damping degree of the polymer profile to framework conditions, such as the weight of the inner module or the impacts acting on the outer module.

In order to be able to flexibly adapt the damping and hardness characteristics of the polymer profile to the framework conditions, it has proved advantageous to provide a device for varying the quantity and/or pressure of the medium introduced into the hollow profile. This device makes it possible to replace the medium introduced into the hollow profile or segments thereof. Furthermore through a change to the internal pressure it is possible to set other damping and hardness characteristics for the hollow profile. Another advantage of such a device is that a hollow profile, without filling, can be placed between the inner and outer modules and then filled with a chosen medium in the fitted state. Thus, the use process of the polymer profile can be facilitated and a suitable medium is determined in situ on the basis of the weight of the modules fitted in the inner frame.

If the polymer profile is used in the case of a parallelepipedic inner module, it is appropriately formed from at least four, substantially mutually abutting profile strands.

A particularly good polymer profile fixing can be achieved in that the clamping device has wedge-shaped clamping surfaces directed against one another. These wedge-shaped, directed against one another clamping surfaces permit a particularly easy, reliable placing of the polymer profile. As a result of the clamping device no additional fixing of the polymer profile is needed. A simple, adhesive securing, e.g. by means of a thin adhesion point, for aiding fixing, is conceivable. As this only acts in a supporting manner, it is possible to avoid on dismantling again disadvantages, such as the problems arising with conventional, mainly adhesive securing. Moreover, through this construction it is ensured that the polymer profile cannot be pressed out of the clamping device even after high vibration amplitudes. Through additional extensions on the clamping device in engagement with the polymer profile an even greater security and reliability can be ensured.

In order to make the polymer profile stronger and more dimensionally stable, it is advantageous to provide a wire mesh which is integrated or embedded therein. Through such a wire mesh the hardness and damping characteristics of the polymer profile can be influenced. This increases the field of application of such a profile, because it is possible to achieve hardnesses which are not possible purely with a polymer material.

To bring about a particularly good damping action, a clamping surface is formed for the polymer profile on the inner frame and another clamping surface cooperating therewith for said polymer profile is formed on the outer frame. As a result of this construction the polymer profile is appropriately held between the two frames and consequently damping occurs to shocks and vibrations acting on the outer frame with respect to the inner frame. This construction also makes it possible for the inner frame to have no contact points with the outer frame.

In an advantageous embodiment the polymer profile is constructed with a sealing function and is in particular tight with respect to dust, water and/or EMC. If the polymer profile has these characteristics, there is no need for an additional rubber bellows for sealing the sides and rear area of the module fitted in the inner frame. Thus, the problems arising in the prior art with the installation of a rubber bellows do not arise with such a support arrangement. It is also possible to achieve EMC-tightness without significant additional expenditure, in that the polymer profile has additives of electrically conducting carbon fibres or particles or an electrically conducting fabric.

Since, unlike in the known systems, the inner frame is no longer suspended on the outer frame by damping elements, it is advantageous that the hardness of the polymer profile in the standing area of the outer frame is greater than in the opposite area. Thus, the inner frame can be vertically centred. The hardness of the polymer profile in the standing area is preferably made higher, so that in normal operation, in addition to the shocks, also the weight force of the modules installed in the inner frame acts thereon and higher forces can be absorbed. This can be particularly easily achieved through a segmentation of the polymer profile, the lower segments being able to have a higher hardness through the introduction of a suitable fluid or air. It is also possible to use different polymer types in order to influence the hardness.

The appropriately polymer material damping and sealing profile can be made from elastomer or rubber and optionally also mixtures thereof, in accordance with the intended use. Elastic, sealing plastics materials or mixtures thereof can also be used.

With a view to desired damping characteristics the profile can be given higher spring rigidity in the Z-direction e.g. by biasing in the X-direction. Thus, the profile can e.g. have an approximately 1.5 times higher spring rigidity in the Z-direction than in the X-direction.

In the configuration of the profile the aim is to obtain in corner areas of the bearing device a largely complimentary shape with respect to the profile, so that a positive engagement is ensured. Thus, an oval sealing profile can have tapering end regions in the engagement areas.

The bearing device between the outer housing and inner vibrating frame should appropriately e.g. in the case of inclined surfaces be constructed in such a way that the wedge-shaped end points or areas have an extension in the height direction Y of the outer housing making it possible to introduce the inner vibrating frame in the horizontal X-direction in unimpeded manner into the inner area of the outer housing.

In the case of an oval hollow seal to be introduced between the inclined surfaces with pretension, adequate expansion areas, e.g. roughly parallel to the inclined surfaces of the bearing device must be provided, so that in the case of shock actions relatively flexible spring suspension characteristics are achieved for the vibrating housing.

A desired rigidity of the damping profile can also be set by the pretension applied to the said damping profile. To this end in the case of inclined surfaces of the bearing device it is possible to make adjustable the relative mutual spacing of said surfaces. In place of inclined surfaces it is also possible to provide cage-like receiving or guiding devices for the sealing profile.

In accordance with the guiding and bearing device for the profile and the forces which are expected, the configuration of the profile can be matched in such a way that also in the case of maximum loading the maximum spacing between outer housing and vibrating frame can be adequately tightly sealed by means of the chosen profile configuration. With a view to the bearing surfaces and edges, the profile design should be such that edge loads on the profile are avoidable.

Profiles of rubber material, e.g. neoprene with a Shore A hardness of 50 or in the range 45 to 60 Shore, with wall thicknesses of approximately 3 to 5 mm for hollow profiles, appear very suitable for a good spring suspension and damping of the forces which occur, even if they are in shock or permanent shock form.

Preferably such a support arrangement is provided in an instrument case for an outer housing and an inner vibrating frame fitted therein. It is particularly advantageous for the vibrating frame to be constructed as a rack and to provided on at least one front side of the outer housing a removable end cover. The polymer profile forms a damping device for the rack in the inner area of the instrument case. Thus, there is no need with such an instrument case to use the complicated vibration damping elements known from the prior art. There is also no need to provide a rubber bellows, which negatively influences the damping action of the damping elements, for sealing the installed modules when the end cover is open.

Through the use of the inventive support arrangement the polymer profile is simultaneously a sealing device for the equipment and modules installable in the rack. Thus, important disadvantages known from the prior art can be overcome through the use of said support arrangement with a polymer profile and a simple, but still flexible, combined damping and sealing system for an instrument case can be obtained.

The invention is described in greater detail hereinafter relative to an embodiment and diagrammatic drawings, in which

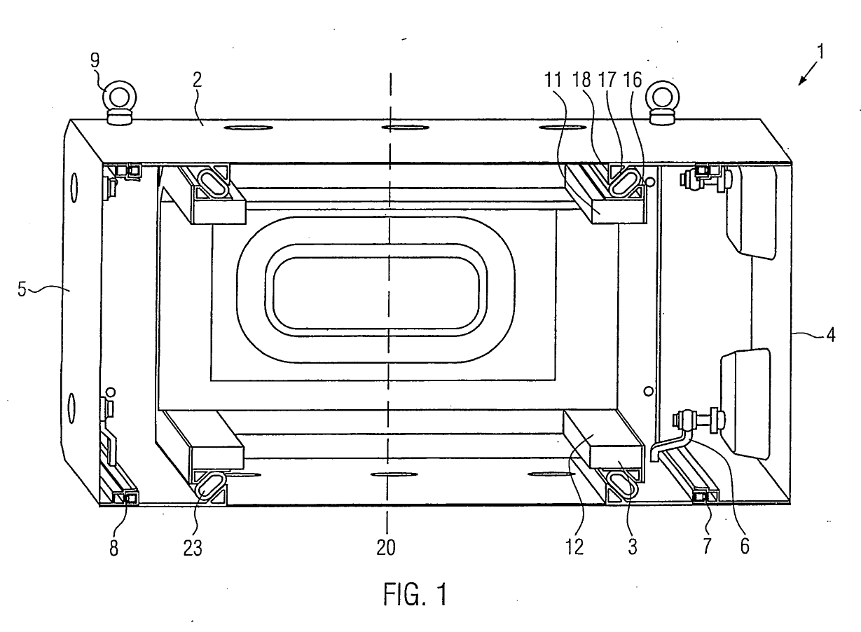

FIG. 1 is a side view of a longitudinal section through an instrument case with an inventive support arrangement;

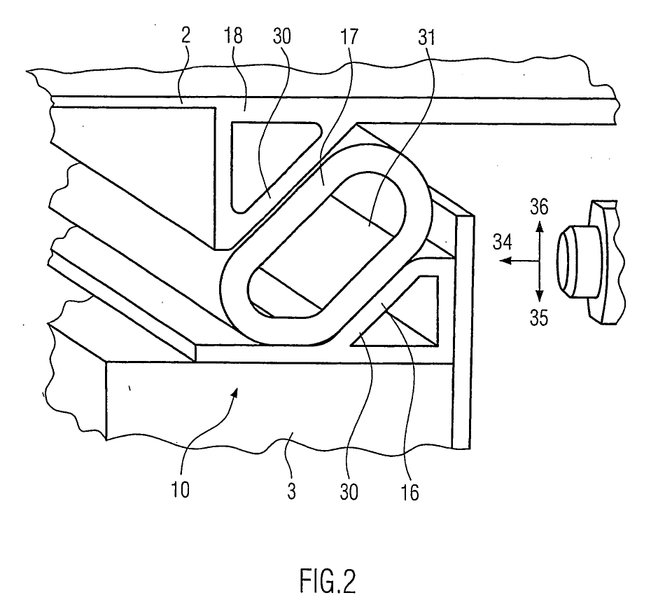

FIG. 2 is a larger scale view of a support arrangement according to FIG. 1, in section in an instrument case; and

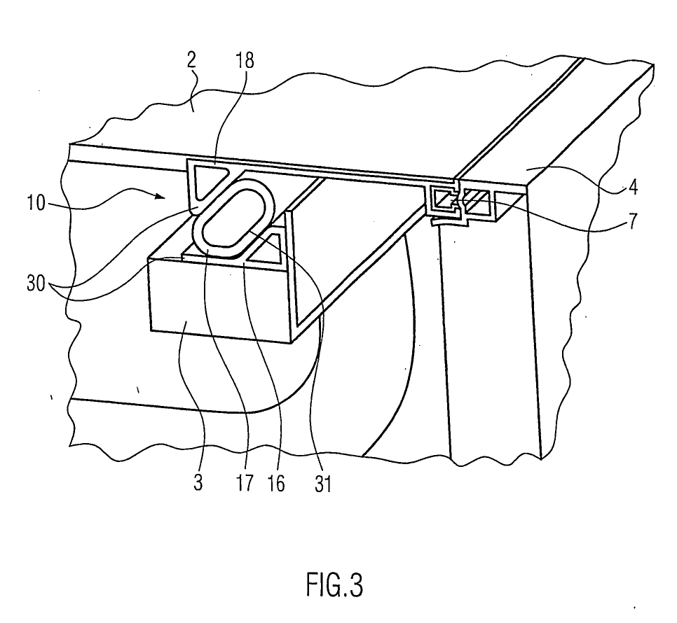

FIG. 3 is a comparable view of the support arrangement of FIG. 2 in an instrument case with an end cover fitted to the front.

FIG. 1 is a longitudinal section of a side view of an instrument or equipment case 1, which comprises an outer module 2, which is in this case a housing, and an inner module 3, which is in the form of a vibrating frame. Equipment case 1 also has a front end cover 4 and a rear end cover 5. Said end covers 4, 5 are fixed with the aid of rotary locks 6 to housing 2. In order to prevent a penetration of moisture or dirt particles into the closed instrument case 1, on the front faces of said case 1 are formed external sealing devices 7, 8. The latter are so constructed that when the end covers 4, 5 are closed, the housing can be sealed in a largely watertight manner. Two transportation rings 9 are visible in the upper area of instrument case 1 and on same can act transportation devices in order to e.g. raise a fully equipped instrument case 1 or for fixing to appropriate devices.

Vibrating frame 3 here has not shown devices in order to be able to receive and fix modules therein. If said modules are fitted in the vibrating frame, with their front panels they close the area between the upper strut 11 and lower strut 12. For damping purposes instrument case 1 has a support arrangement 10 formed by an outer part of a clamping device 18 and an inner part of a clamping device 16. Between said two parts of clamping devices 16, 18 is provided a polymer profile 17. In the embodiment shown the polymer profile 17 is oval and constructed as a hollow profile similar to a hose.

Instrument case 1 has in this embodiment two bearing devices 30 for polymer profile 17, 23. These two bearing devices 30 are located at both ends of instrument case 1. In the embodiment according to FIG. 1 the two bearing devices 30 and also the polymer profile 17, 23 located therein pass round the entire inner circumference of instrument case 1. The two bearing devices 30 are constructed symmetrically or mirror symmetrically to central axis 20. Such a construction consequently makes it possible to damp or eliminate in optimum manner for the installed modules forces acting horizontally, vertically and/or laterally on outer housing 2 and/or inner vibrating frame 3. Through the use of the support arrangements 10 in instrument case 1, which are constructed axially symmetrically to central axis 20, it is possible to achieve a damping action in all three coordinate directions.

FIG. 2 shows in detail form a support arrangement 10 in a sectional, larger scale view. The polymer profile 17 used here has a cavity 31, which can be filled with a random medium, so that the damping characteristics of polymer profile 17 can be influenced and adjusted. The outer part of clamping device 18 is provided as a wedge-shaped projection on outer module 2. The inner part of clamping device 16 faces the wedge-shaped, outer part of clamping device 18. Clamping device 16 forms the counterpart to the outer clamping device 18 and is fixed to the inner module 3. With the support arrangement 10 shown in FIG. 2 it is possible to absorb and damp forces in directions 34, 35, 36 and the forces resulting therefrom.

As can be gathered from FIG. 2, the polymer profile is in positive engagement both with the outer part of clamping device 18 and also the inner part of clamping device 16. Thus, with said support arrangement 10, besides the damping of inner module 3, it is also possible to prevent the penetration of dirt or moisture through the slit between the inner and outer modules. There is no need for using a rubber bellows, as in the prior art.

FIG. 3 also shows a support arrangement 10 in an instrument case 1 in a larger detail. The outer part of clamping device 18 is fitted to housing 2 and engaging and force-clamped thereon is provided the polymer profile 17, in the form of a hollow profile. The inner part of clamping device 16 faces the outer part of clamping device 18 and is fixed to the inner vibrating frame 3. In FIG. 3 the outer sealing device 7 is shown and which together with the end cover 4 seals the instrument case 1 against external environmental influences. The sealing action of the support arrangement 10 comes fully into effect when the end cover 4 is removed and equipment or modules (not shown) installed in vibrating frame 3 are present.

Thus, the support arrangement 10 according to the invention provides a simple, flexible concept for fitting an inner frame to an outer frame in vibration-damped manner, whilst simultaneously achieving an optimum sealing function.

1-18. (canceled)

19. A support arrangement for an inner module in an outer module, particularly for an inner vibrating frame in an outer frame of an outer module,
with a damping device between the inner and outer modules for receiving forces acting in up to three coordinate directions relative to the inner and outer module,
in which the damping device essentially is constructed as at least one elastic polymer profile, particularly two polymer profiles, running round between the inner and outer module, wherein
the inner and outer module are equipped with a bearing device for the elastic polymer profile or profiles,
the polymer profile is provided between the inner and outer module in the vicinity of the bearing device and is given a sealing function, being in particular dust, water and/or EMC-tight and
the bearing device has two surfaces directed against one another, which are in particular parallel and inclined, and between which is provided the polymer profile.

20. The arrangement according to claim 19, wherein
in each case at least one bearing device for the polymer profile is provided on both end regions of the inner module and
wherein the two bearing devices are designed in substantially mirror symmetrical manner to the “central axis” of the inner module.

21. The arrangement according to claim 19, wherein the bearing device is constructed as a clamping device.

22. The arrangement according to claim 19, wherein the polymer profile is constructed as a solid profile.

23. The arrangement according to claim 19, wherein the polymer profile is constructed as a hollow profile.

24. The arrangement according to claim 22, wherein the polymer profile is in large-area operative connection with the bearing device.

25. The arrangement according to claim 19, wherein the polymer profile is constructed as an annular hollow profile.

26. The arrangement according to claim 19, wherein the polymer profile is constructed as an oval hollow profile.

27. The arrangement according to claim 19, wherein the polymer profile is constructed in an integral, segmented manner.

28. The arrangement according to claim 19, wherein the polymer profile is constructed with partial areas having different hardness and damping characteristics.

29. The arrangement according to claim 26, wherein the hardness and damping characteristics can be adjusted by means of a medium introduced into a hollow profile or segments of the hollow profile of the polymer profile and the clamping of the polymer profile in the bearing device.

30. The arrangement according to claim 22, wherein there is a device for varying the quantity and pressure of the medium introduced into the hollow profile.

31. The arrangement according to claim 19, wherein in the case of a parallelepipedic inner module, the polymer profile is formed by at least four, substantially mutually abutting profile strands.

32. The arrangement according to claim 21, wherein the clamping device has wedge-shaped inclined clamping surfaces for retaining the polymer profile, directed against one another.

33. The arrangement according to claim 19, wherein the polymer profile has a wire mesh which is integrated or embedded therein.

34. The arrangement according to claim 22, where in a clamping surface for the polymer profile is formed on the inner frame and a clamping surface for the polymer profile cooperating therewith is formed on the outer frame.

35. The arrangement according to claim 19, wherein in a standing area of the outer frame, the hardness of the polymer profile is greater than in the opposite area.

36. An instrument case with a support arrangement for an inner module in an outer module, particularly for an inner vibrating frame in an outer frame of an outer module,
with a damping device between the inner and outer modules for receiving forces acting in up to three coordinate directions relative to the inner and outer module,
in which the damping device essentially is constructed as at least one elastic polymer profile, particularly two polymer profiles, running round between the inner and outer module, wherein
the inner and outer modules are equipped with a bearing device for the elastic polymer profile or profiles,
the polymer profile is provided between the inner and outer module in the vicinity of the bearing device and is given a sealing function, being in particular dust, water and/or EMC-tight and
the bearing device has two surfaces directed against one another, which are in particular parallel and inclined, and between which is provided the polymer profile, fitted therein,
and an outer housing and an inner vibrating frame is fitted in the support arrangement.

37. The instrument case according to claim 36, wherein the vibrating frame is constructed as a rack,
a removable end cover is provided on at least one front surface of the outer housing and
the polymer profile forms a damping device for the rack in the inner area of the instrument case.

38. The instrument case according to claim 37, wherein the polymer profile forms a sealing device for equipment and modules insertable in the rack.
